(19) United States
(12) Patent Application Publication
(10) Pub. No.: US 2016/0319158 A1
(43) Pub. Date: Nov. 3, 2016

(54) PROCESS FOR PRODUCING A BLOCK COPOLYMER FILM ON A SUBSTRATE

(71) Applicants: ARKEMA FRANCE, Colombes (FR); UNIVERSITE DE BORDEAUX, Bordeaux (FR); INSTITUT POLYTECHNIQUE DE BORDEAUX, Talence Cedex (FR); CENTRE NATIONAL DE LA RECHERCHE SCIENTIFIQUE (CNRS), Paris (FR)

(72) Inventors: Guillaume FLEURY, Bordeaux (FR); Christophe NAVARRO, Bayonne (FR); Georges HADZIIOANNOU, Leognan (FR); Celia NICOLET, Talence (FR); Xavier CHEVALIER, Grenoble (FR); Chrystilla REBOUL, Talence (FR); Veronica CASTILLO, Talence (FR); Gilles PECASTAINGS, Bordeaux (FR)

(73) Assignees: CENTRE NATIONAL DE LA RECHERCHE SCIENTIFIQUE (CNRS), Paris Cedex 14 (FR); UNIVERSITE DE BORDEAUX, Bordeaux (FR); INSTITUT POLYTECHNIQUE DE BORDEAUX, Talence Cedex (FR); ARKEMA FRANCE, Colombes (FR)

(21) Appl. No.: 15/103,748

(22) PCT Filed: Dec. 10, 2014
(86) PCT No.: PCT/FR2014/053254

§ 371 Date: Jun. 10, 2016

(30) Foreign Application Priority Data
Dec. 13, 2013 (FR) 1362585

(51) Int. Cl. C09D 187/00; B05D 3/06; H01L 21/027; B01J 31/06

(52) U.S. Cl. CPC C09D 187/005; B01J 31/06; B05D 3/06; H01L 21/0271

(57) ABSTRACT

The invention relates to a process for producing a film of self-assembled block copolymers on a substrate, said process consisting in carrying out a simultaneous deposition of block copolymer and of random copolymer by means of a solution containing a blend of block copolymer and of random copolymer of different chemical nature and which are immiscible, then in carrying out an annealing treatment allowing the promotion of the phase segregation inherent in the self-assembly of block copolymers.

### FIELD OF THE INVENTION

The present invention relates to a process for producing a self-assembled block copolymer film on a substrate making it possible to neutralize the interfacial energies between said block copolymer film and the substrate comprising the formation of a layer of random copolymer capable of neutralizing said interfacial energies between the block copolymer film and the substrate in a thin-film configuration.

The process applies to the field of lithography in which the block copolymer films constitute masks for lithography, or information storage, in which the block copolymer films make it possible to localize magnetic particles. The process also applies to the manufacture of catalysis supports or porous membranes for which one of the domains of the block copolymer is degraded in order to obtain a porous structure. The process advantageously applies to the field of nanolithography using block copolymer masks.

### PRIOR ART

Many advanced lithography processes based on the self-assembly of block copolymers (BCs) involve PS-b-PMMA (polystyrene-block-poly(methyl methacrylate)) masks. However, PS is a poor mask for etching, since it has a low resistance to the plasmas inherent in the etching step. Consequently, this system does not allow optimum transfer of the patterns to the substrate. Furthermore, the limited phase separation between the PS and the PMMA due to the low Flory-Huggins parameter x of this system does not make it possible to obtain domain sizes of less than about 20 nm, consequently limiting the final resolution of the mask. In order to overcome these deficiencies, in “Polylactide-Poly(dimethylsiloxane)-Polylactide Triblock Copolymers as Multifunctional Materials for Nanolithographic Applications”. ACS Nano. 4(2): p. 725-732, Rodwogin, M. D., et al. describe groups containing Si or Fe atoms, such as PDMS (poly(dimethylsiloxane)), polyhedral oligomeric silsesquioxane (POSS), or else poly(ferrocenylsilane) (PFS), introduced into block copolymers acting as masks. These copolymers can form well-separated domains similar to those of PS-b-PMMA, but, contrary to the latter domains, the oxidation of the inorganic blocks during the etching treatments forms a layer of oxide which is much more resistant to etching, thereby making it possible to keep intact the pattern of the polymer constituting the lithography mask.

In the article “Orientation-Controlled Self-Assembled Nanolithography Using a Polystyrene-Polydimethylsiloxane Block Copolymer”. Nano Letters, 2007. 7(7): p. 2046-2050, Jung and Ross suggest that the ideal block copolymer mask should have a high value of x, and that one of the blocks should be highly resistant to etching. A high value of x between the blocks promotes the formation of pure and well-defined domains on the entire substrate, as is explained by Bang, J. et al., in “Defect-Free Nanoporous Thin Films from ABC Triblock Copolymers”. J. Am. Chem. Soc., 2006. 128: p. 7622, i.e. a decrease in line roughness. x is equal to 0.04 for the PS/PMMA pair, at 393K, whereas, for PS/PDMS (poly(dimethylsiloxane)), it is 0.191, for PS/P2VP (poly (2-vinylpyridine)) it is 0.178, for PS/PEO (poly(ethylene oxide)) it is 0.077 and for PDMS/PLA (poly(lactic acid)) it is 1.1. This parameter, combined with the strong contrast during etching between PLA and PDMS, allow a better definition of the domains and therefore make it possible to approach domain sizes of less than 22 nm. All these systems have shown a good organization with domains having a limiting size of less than 10 nm, according to certain conditions. However, many systems which have a high value of x are organized by virtue of solvent-vapor annealing, since excessively high temperatures would be required for thermal annealing, and the chemical integrity of the blocks would not necessarily be preserved.

A process for producing a polymer structure having a surface with a plurality of functionalized surface domains is also known from document WO 2010/115243. The method comprises the production of a composition comprising at least one surface polymer, at least one block copolymer and at least one common solvent, in which composition the block copolymers have the general formula A-B-C in which A is a polymer of the same type as the polymer of the surface polymer and is miscible with the surface polymer, B being a polymer which is immiscible with the polymer A, and C being an end group which is a reactive molecule or an oligomer.

Among the constituent blocks of the block copolymers which are of interest, mention may be made of PDMS, since it has already been used in mild lithography, i.e. not based on interactions with light, or specifically as an ink pad or mold. PDMS has one of the lowest glass transition temperatures Tg of polymer materials. It has a high heat stability, a low UV-ray adsorption and highly flexible chains. Furthermore, the silicon atoms of PDMS confer on it good resistance to reactive ion etching (RIE), thus making it possible to correctly transfer the pattern formed by the domains to the layer of substrate.

Another block of interest that can advantageously be combined with PDMS is PLA.

Poly(lactic acid) (PLA) stands out because of its degradability, which makes it possible to easily degrade it chemically or via plasma during the step of creating the copolymer mask (it is twice as sensitive to etching as PS, which means that it can be degraded much more easily). It is, in addition, easy to synthesize and inexpensive.

It has been demonstrated on several occasions that the grafting of a random copolymer brush, namely the use of a PS-r-PMMA random copolymer brush, makes it possible to control the surface energy of the substrate, as can be read with the following authors: Mansky, P., et al., “Controlling polymer-surface interactions with random copolymer brushes”. Science, 1997. 275: p. 1458-1460, Han, E., et al., “Effect of Composition of Substrate-Modifying Random Copolymers on the Orientation of Symmetric and Asymmetric Diblock Copolymer Domains”. Macromolecules, 2008. 41(23): p. 9090-9097, Ryu, D. Y., et al., “Cylindrical Microdomain Orientation of PS-b-PMMA on the Balanced Interfacial Interactions: Composition Effect of Block Copolymers. Macromolecules, 2009”. 42(13): p. 4902-4906, In, I., et al., “Side-Chain-Grafted Random Copolymer Brushes as Neutral Surfaces for Controlling the Orientation of Block Copolymer Microdomains in Thin Films”. Langmuir, 2006. 22(18): p. 7855-7860, Han, E., et al., “Perpendicular Orientation of Domains in Cylinder-Forming Block Copolymer Thick Films by Controlled Interfacial Interactions. Macromolecules, 2009”. 42(13): p. 4896-4901; in order to obtain normally unstable morphologies, such as cylinders perpendicular to the substrate in a thin-film configuration for a PS-b-PMMA block copolymer. The surface energy of the modified substrate is controlled by varying the volume fractions of repeating units of the random copolymer. This technique is used since it is simple and rapid and makes it possible to easily vary the surface energies in order to equilibrate the preferential interactions between the domains of the block copolymer and the substrate grafted with the random polymer.

Most of the work where a random copolymer brush is used in order to minimize the surface energies shows the use of a PS-r-PMMA (PS/PMMA random copolymer) brush for controlling the organization of a PS-b-PMMA. Ji et al. in “Generalization of the Use of Random Copolymers To Control the Wetting Behavior of Block Copolymer Films. Macromolecules, 2008”. 41(23): p. 9098-9103 have demonstrated the use of a PS-r-P2VP random copolymer in order to control the orientation of a PS-b-P2VP, a methodology similar to that used in the case of the PS/PMMA.

However, the grafting of a random copolymer brush requires thermal annealing of the random copolymer films at high temperature. Indeed, the thermal annealing can last up to 48 h in a furnace under vacuum at a temperature above the glass transition temperature of the random copolymer. This step is costly in terms of energy and in terms of time.

The applicant has sought to obtain a process for producing a film of self-assembled block copolymers on a substrate making it possible to neutralize the interfacial energies between said block copolymer film and the substrate which is less expensive in terms of time and in terms of energy than the known processes. The process provided advantageously makes it possible to control the orientation of the mesostructure formed by the self-assembly of the block copolymer and in particular for a mesostructure of cylinders oriented perpendicular to the substrate or of lamellae oriented perpendicular to the substrate

In the article by Kim et al. entitled “Controlling Orientation and Order in Block Copolymer Thin Films” Advanced Materials, 20(24): 4851-4856, another alternative solution is proposed for controlling the orientation of a mesostructure obtained from the self-assembly of a block copolymer. The study carried out consists in adding PS—OH homopolymer to a solution containing the PS-b-PEO diblock copolymer. It is demonstrated, by neutron reflectivity measurement, that the PS—OH chains form a thin layer at the block copolymer film/substrate interface. Consequently, during an annealing for promoting the self-assembly of the PS-b-PEO copolymer, the homopolymer migrates toward the substrate and behaves in the same way as a grafted brush of homopolymer. The PS—OH homopolymer is then of the same nature as one of the constituents of the block copolymer. This solution does not comprise a thermal annealing step required for the grafting of a brush as previously described, but does not address the problem of controlling the orientation of the block copolymer domains.

Few studies make reference to the control of the orientation of the domains by using random or gradient copolymers, the constituent monomers of which are at least partly different than those present in the block copolymer, including in the case of systems other than PS-b-PMMA.

Keen et al., in “Control of the Orientation of Symmetric Poly(styrene)-block-poly(d,l-lactide) Block Copolymers Using Statistical Copolymers of Dissimilar Composition. Langmuir, 2012”, have demonstrated the use of a PS-r-PMMA random copolymer for controlling the orientation of a PS-b-PLA. However, it is important to note that, in this case, one of the constituents of the random copolymer is chemically identical to one of the constituents of the block copolymer.

However, for certain systems such as PDMS/PLA, the synthesis of random copolymers from the respective monomers, making it possible to apply the approach described above, cannot be carried out in the current prior art.

The applicant has also been interested in bypassing this problem by controlling the surface energies between the substrate and the block copolymer using a material of different chemical nature but which provides the same end result in terms of functionality, namely the obtaining of a layer of random polymer between the block polymer and the substrate which neutralizes the interfacial energies without a grafting step.

Reference may, in addition, be made to the prior art consisting of the following publications:

the document by Ming Jiang et al. entitled “Miscibility and Morphology of AB/C-type blends composed of block copolymers and homopolymer or random copolymer, 2A). Oblends with random copolymer effect”, Macromolecular chemistry and Physics, Wiley-VCH VERLAG, WEINHEIM, DE, vol. 196, n° 3, Mar. 1, 1995 (1995-03-01), Pages 803-814, XP000496316, ISSN:1022-1352, D0I:10.1002/MACP.1995.021960310-pages 805, paragraph 3-page 806, paragraph 2, page 806, table 2, page 807, paragraph 2-page 810, paragraph 1. Said document describes a process for producing a self-assembled block copolymer film consisting of the poly(isoprene-b-methyl methacrylate) block copolymer and of the poly(styrene-acrylonitrile) random copolymer. The two copolymers are of different chemical nature and are immiscible under certain conditions, such as the ratio between the number-average molecular mass of the poly(styrene-acrylonitrile) and the number-average molecular mass of the poly(methyl methacrylate); or alternatively the mass ratio between the poly(methyl methacrylate) and the poly(styrene-acrylonitrile). However, the process described in said document does not comprise the deposition, on a substrate, of a solution containing a blend of block copolymer and of random or gradient copolymer. The solutions obtained after blending of the block copolymer and of the random copolymer are placed in Teflon cells so as to allow the evaporation of the solvent, THF, and thus to obtain dry films (page 806, first paragraph). The Teflon does not therefore serve as a substrate, but simply as a constituent material of the evaporation cells. In addition, said document is a scientific publication aimed at studying the misciblility and morphology of a blend comprising a block copolymer and a random copolymer and no application (use) of such a blend is described in said document;

the document by Qingling Zhang et al. entitled “Controlled Placement of CdSe Nanoparticules in Diblock Copolymer Templates by Electrophoretic Deposition”, NANO LETTERS, AMERICAN CHEMICAL SOCIETY, US, vol. 5 n° 2, Feb. 1, 2005 (2005-02-01), pages 357-361, XP009132829, ISSN: 1530-6984, D0I: 10.1021/NL048103T [retrieved on 2005-01-06] page 358, left-hand column, paragraph 2]. Said document describes a process for electrodeposition of CdSe nanoparticles in the nanopores of a support. Said document also describes such a support, obtained from a porous film comprising a polystyrene network, said film being obtained by treating a copolymer comprising poly(methyl methacrylate) blocks and polystyrene blocks with ultraviolet radiation and plasma. However, the process described in said document does not indicate that the block copolymer and the random copolymer are of different chemical nature and are immiscible. On the contrary, in the experimental section, page 360, column 2, it is indicated that the random copolymer is a poly(styrene-methyl methacrylate), the ends of which are hydroxylated. The fact that the diblock copolymer is a poly(styrene-block-methyl methacrylate) makes it possible to confirm that the two copolymers are of the same chemical nature and are miscible. In addition, no application other than that of an electrodeposition support is described in the document.

The aim of the invention is therefore to remedy the drawbacks of the prior art by providing a process for producing a film of self-assembled block copolymers having a controlled orientation on a substrate, said process consisting in carrying out a simultaneous deposition of block copolymer and of random copolymer by means of a solution containing a blend of block copolymer and of random copolymer of different chemical nature, then in carrying out a thermal annealing treatment allowing the promotion of the phase segregation inherent in the self-assembly of block copolymers. The block copolymer and the random copolymer forming the blend are advantageously immiscible.

A subject of the invention is more particularly a process for producing a film of self-assembled block copolymers on a substrate, mainly characterized in that it comprises the following steps:

deposition, on a substrate, of a solution containing a blend of block copolymer and of random or gradient copolymer of different chemical nature and which are immiscible,

annealing treatment allowing the promotion of the phase segregation inherent in the self-assembly of block copolymers.

Advantageously, the use of random or gradient copolymers, the monomers of which are different than those present respectively in each of the blocks of the block copolymer in the solution deposited, makes it possible to effectively solve the problem set out above and in particular to control the orientation of the mesostructure formed by the self-assembly of a block copolymer via a random copolymer which is not chemically related to the block copolymer.

A subject of the invention is also a film obtained by means of the process previously described, said film constituting a mask for lithography applications or a support for the localization of magnetic particles for information storage or guides for the formation of inorganic structures.

A subject of the invention is also a film obtained by means of the process described above, said film constituting a porous membrane or a catalyst support after elimination of one of the domains formed during the self-assembly of the block copolymer.

According to other characteristics of the invention:

the block copolymer has the general formula A-b-B or A-b-B-b-A and the random copolymer has the general formula C-r-D; the monomers of the random copolymer being different than those present respectively in each of the blocks of the block copolymer,

the block copolymer and the random copolymer are immiscible,

advantageously, the annealing treatment is obtained by thermal or solvent-vapor treatment or microwave treatment,

the random or gradient copolymer is prepared by radical polymerization,

the random or gradient copolymer is prepared by controlled radical polymerization,

the random or gradient copolymer is prepared by nitroxide-controlled radical polymerization,

the nitroxide is N-(tert-butyl)-1-diethylphosphono-2,2-dimethylpropyl nitroxide,

the block copolymer is chosen from linear or star diblock copolymers or triblock copolymers,

the block copolymer comprises at least one PLA block and at least one PDMS block,

the random or gradient copolymer comprises methyl methacrylate and styrene,

the annealing treatment is obtained by thermal or solvent-vapor treatment or microwave treatment.

The invention also relates to the use of a film obtained by means of the process previously described, as a mask for lithography applications, a support for discretized information storage or guides for the formation of inorganic structures.

The invention also relates to the use of a film obtained by means of the process previously described, as a porous membrane or a catalyst support.

Other particularities and advantages of the invention will emerge on reading the description given by way of illustrative and nonlimiting example, with reference to the figures in which:

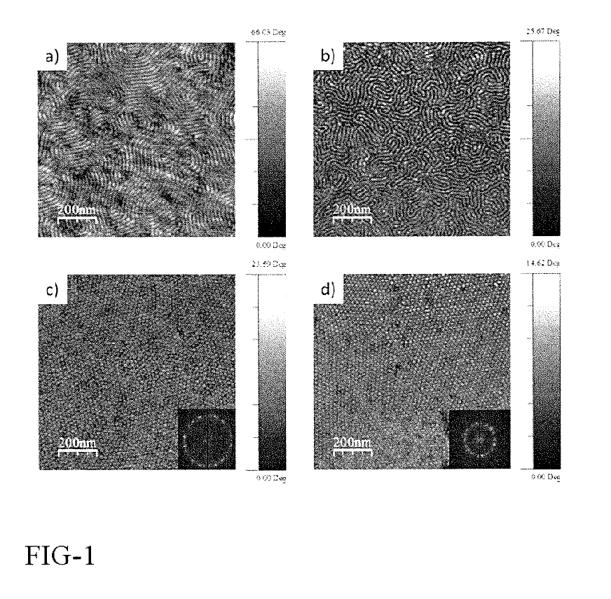

FIG. 1 represents four images (a), (b), (c) and (d) obtained according to the imaging technique known as atomic force microscopy (AFM),

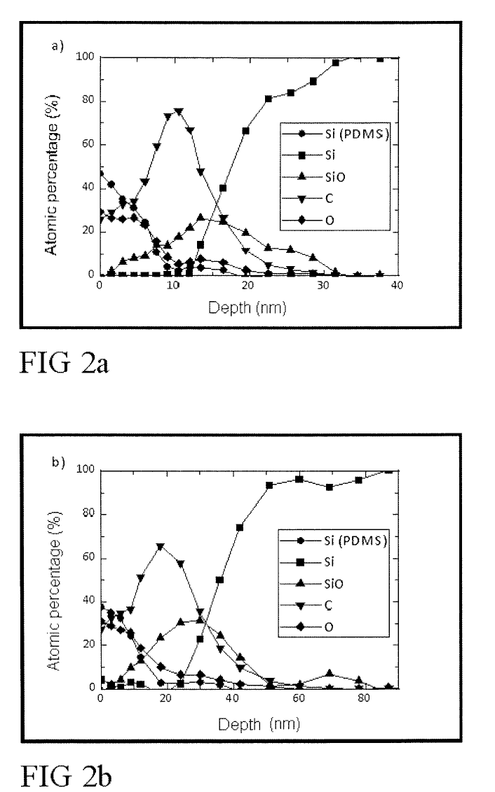

FIG. 2a represents Auger electron emission spectra for a film obtained by means of the process for depositing a brush of random copolymers according to the prior art,

FIG. 2b represents Auger electron emission spectra for a film obtained by means of the process according to the invention.

### DETAILED DESCRIPTION

### The Random or Gradient Copolymers:

The term “random or gradient copolymers” is intended to mean, in the present invention, macromolecules in which the distribution of the monomer units obeys random laws.

The random or gradient copolymers used in the invention are of the general formula C-s-D, and their constituent monomers are different than those present respectively in each of the blocks of the block copolymer used.

The random copolymers can be obtained by any route, among which mention may be made of polycondensation, ring-opening polymerization or anionic, cationic or radical polymerization, it being possible for the latter to be controlled or uncontrolled. When the polymers are prepared by radical polymerization or telomerization, it can be controlled by any known technique, such as NMP (Nitroxide Mediated Polymerization), RAFT (Reversible Addition and Fragmentation Transfer), ATRP (Atom Transfer Radical Polymerization), INIFERTER (Initiator-Transfer-Termination), RITP (Reverse Iodine Transfer Polymerization) or ITP (Iodine Transfer Polymerization).

Preference will be given to polymerization processes which do not involve metals. Preferably, the polymers are prepared by radical polymerization, and more particularly by controlled radical polymerization, even more particularly by nitroxide-controlled polymerization.

More particularly, the nitroxides resulting from the alkoxyamines derived from the stable free radical (1) are preferred,

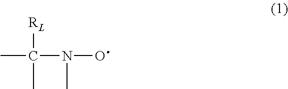

in which the radical RL has a molar mass greater than 15.0342 g/mol. The radical RL may be a halogen atom such as chlorine, bromine or iodine, a saturated or unsaturated, linear, branched or cyclic, hydrocarbon-based group, such as an alkyl or phenyl radical, or an ester group —COOR or an alkoxyl —OR, or a phosphonate group PO(OR)₂, as long as it has a molar mass greater than 15.0342. The radical RL, which is monovalent, is said to be in the β position with respect to the nitrogen atom of the nitroxide radical. The remaining valences of the carbon atom and of the nitrogen atom in formula (1) can be bonded to various radicals, such as a hydrogen atom, or a hydrocarbon-based radical, for instance an alkyl, aryl or arylalkyl radical, comprising from 1 to 10 carbon atoms. It is not out of the question for the carbon atom and the nitrogen atom in formula (1) to be linked to one another by means of a divalent radical, so as to form a ring. Preferably however, the remaining valences of the carbon atom and of the nitrogen atom of formula (1) are bonded to monovalent radicals. Preferably, the radical RL has a molar mass greater than 30 g/mol. The radical RL can, for example, have a molar mass between 40 and 450 g/mol. By way of example, the radical RL may be a radical comprising a phosphoryl group, it being possible for said radical RL to be represented by the formula:

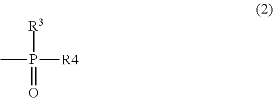

in which R³ and R⁴, which may be identical or different, can be chosen from alkyl, cycloalkyl, alkoxyl, aryloxyl, aryl, aralkyloxyl, perfluoroalkyl and aralkyl radicals, and can comprise from 1 to 20 carbon atoms. R³ and/or R⁴ can also be a halogen atom, such as a chlorine or bromine or fluorine or iodine atom. The radical RL can also comprise at least one aromatic ring such as for the phenyl radical or the naphthyl radical, it being possible for the latter to be substituted, for example with an alkyl radical comprising from 1 to 4 carbon atoms.

More particularly, the alkoxyamines derived from the following stable radicals are preferred:
N-(tert-butyl)-1-phenyl-2-methyl propyl nitroxide,
N-(tert-butyl)-1-(2-naphthyl)-2-methyl propyl nitroxide,
N-(tert-butyl)-1-diethylphosphono-2,2-dimethyl propyl nitroxide,
N-(tert-butyl)-1-dibenzylphosphono-2,2-dimethyl propyl nitroxide,
N-phenyl-1-diethylphosphono-2,2-dimethyl propyl nitroxide,
N-phenyl-1-diethylphosphono-1-methyl ethyl nitroxide,
N-(1-phenyl-2-methyl propyl)-1-diethylphosphono-1-methyl ethyl nitroxide,
4-oxo-2,2,6,6-tetramethyl-1-piperidinyloxy,
2,4,6-tri-(tert-butyl)phenoxy.

The alkoxyamines used in controlled radical polymerization must allow good control of the linking of the monomers. Thus, they do not all allow good control of certain monomers. For example, the alkoxyamines derived from TEMPO make it possible to control only a limited number of monomers, the same is true for the alkoxyamines derived from 2,2,5-trimethyl-4-phenyl-3-azahexane-3-nitroxide (TIPNO). On the other hand, other alkoxyamines derived from nitroxides corresponding to formula (1), particularly those derived from nitroxides corresponding to formula (2) and even more particularly those derived from N-(tert-butyl)-1-diethylphosphono-2,2-dimethyl propyl nitroxide, make it possible to broaden the controlled radical polymerization of these monomers to a large number of monomers.

In addition, the alkoyamine opening temperature also influences the economic factor. The use of low temperatures will be preferred in order to minimize industrial difficulties. The alkoxyamines derived from nitroxides corresponding to formula (1), particularly those derived from nitroxides corresponding to formula (2) and even more particularly those derived from N-(tert-butyl)-1-diethylphosphono-2,2-dimethyl propyl nitroxide, will therefore be preferred to those derived from TEMPO or 2,2,5-trimethyl-4-phenyl-3-azahexane-3-nitroxide (TIPNO).

### The Constituent Monomers of the Random Copolymers and of the Block Copolymers:

The constituent monomers of the random copolymers and of the block copolymers (a minimum of two) will be chosen from vinyl, vinylidene, diene, olefinic, allyl or (meth)acrylic monomers. These monomers are more particularly chosen from vinylaromatic monomers, such as styrene or substituted styrenes, in particular α-methylstyrene, acrylic monomers, such as acrylic acid or its salts, alkyl, cycloalkyl or aryl acrylates, such as methyl, ethyl, butyl, ethylhexyl or phenyl acrylate, hydroxyalkyl acrylates, such as 2-hydroxyethyl acrylate, ether alkyl acrylates, such as 2-methoxyethyl acrylate, alkoxy- or aryloxypolyalkylene glycol acrylates, such as methoxypolyethylene glycol acrylates, ethoxypolyethylene glycol acrylates, methoxypolypropylene glycol acrylates, methoxypolyethylene glycol-polypropylene glycol acrylates or mixtures thereof, aminoalkyl acrylates, such as 2-(dimethylamino)ethyl acrylate (ADAME), fluoroacrylates, silylated acrylates, phosphorus-comprising acrylates, such as alkylene glycol acrylate phosphates, glycidyl acrylate or dicyclopentenyloxyethyl acrylate, methacrylic monomers, such as methacrylic acid or its salts, alkyl, cycloalkyl, alkenyl or aryl methacrylates, such as methyl (MMA), lauryl, cyclohexyl, allyl, phenyl or naphthyl methacrylate, hydroxyalkyl methacrylates, such as 2-hydroxyethyl methacrylate or 2-hydroxypropyl methacrylate, ether alkyl methacrylates, such as 2-ethoxyethyl methacrylate, alkoxy- or aryloxypolyalkylene glycol methacrylates, such as methoxypolyethylene glycol methacrylates, ethoxypolyethylene glycol methacrylates, methoxypolypropylene glycol methacrylates, methoxypolyethylene glycol-polypropylene glycol methacrylates or mixtures thereof, aminoalkyl methacrylates, such as 2-(dimethylamino)ethyl methacrylate (MADAME), fluoromethacrylates, such as 2,2,2-trifluoroethyl methacrylate, silylated methacrylates, such as 3-methacryloyloxypropyltrimethylsilane, phosphorus-comprising methacrylates, such as alkylene glycol methacrylate phosphates, hydroxyethylimidazolidone methacrylate, hydroxyethylimidazolidinone methacrylate or 2-(2-oxo-1-imidazolidinyl)ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamidopropyltrimethylammonium chloride (MAPTAC), glycidyl methacrylate, dicyclopentenyloxyethyl methacrylate, itaconic acid, maleic acid or its salts, maleic anhydride, alkyl or alkoxy- or aryloxypolyalkylene glycol maleates or hemimaleates, vinylpyridine, vinylpyrrolidinone, (alkoxy)poly(alkylene glycol) vinyl ethers or divinyl ethers, such as methoxypoly(ethylene glycol) vinyl ether or poly(ethylene glycol) divinyl ether, olefinic monomers, among which may be mentioned ethylene, butene, hexene and 1-octene, diene monomers, including butadiene or isoprene, as well as fluoroolefinic monomers and vinylidene monomers, among which may be mentioned vinylidene fluoride.

Preferably, the constituent monomers of the random copolymers will be chosen from styrene monomers or (meth)acrylic monomers, and more particularly styrene and methyl methacrylate.

Regarding the number-average molecular mass of the random copolymers used in the invention, it may be between 500 g/mol and 100 000 g/mol, preferably between 1000 g/mol and 20 000 g/mol, and even more particularly between 2000 g/mol and 10 000 g/mol, with a dispersity index of from 1.00 to 10, preferably from 1.05 to 3 and more particularly between 1.05 and 2.

The block copolymers used in the invention may be of any type (diblock, triblock, multiblock, gradient, star) provided that their constituent monomers are of a chemical nature different than those present in the random copolymers used in the invention.

### The Block Copolymers

The term “block copolymer” is intended to mean a polymer comprising at least two copolymer blocks as defined below, the two copolymer blocks being different than one another and having a phase segregation parameter such that they are not miscible and separate into nanodomains.

The block copolymers used in the invention have the general formula A-b-B or A-b-B-b-A and can be prepared via any synthesis route, such as anionic polymerization, oligomer polycondensation, ring-opening polymerization, or else controlled radical polymerization.

The constituent blocks may be chosen from the following blocks:
PLA, PDMS, poly(trimethyl carbonate) (PTMC), polycaprolactone (PCL).

According to one variant of the invention, the block copolymers used in the invention will be chosen from the following:
PLA-PDMS, PLA-PDMS-PLA, PTMC-PDMS-PTMC, PCL-PDMS-PCL, PTMC-PCL, PTMC-PCL-PTMC and PCL-PTMC-PCL, and more particularly PLA-PDMS-PLA and PTMC-PDMS-PTMC.

According to another variant of the invention, consideration may also be given to block copolymers, one of the blocks of which comprises either styrene, or styrene and at least one comonomer X, the other block of which comprising either methyl methacrylate, or methyl methacrylate and at least one comonomer Y, X being chosen from the following entities: styrene, which is hydrogenated or partially hydrogenated, cyclohexadiene, cyclohexene, cyclohexane, styrene substituted by one or more fluoroalkyl groups, or mixtures thereof, in proportions by mass of X ranging from 1% to 99% and preferably from 10% to 80%, with respect to the block comprising styrene; Y being chosen from the following entities: fluoroalkyl (meth)acrylate, particularly trifluoroethyl methacrylate, dimethylaminoethyl (meth)acrylate, globular (meth)acrylates, such as isobornyl (meth)acrylate or halogenated isobornyl (meth)acrylate, halogenated alkyl (meth)acrylate, naphthyl (meth)acrylate, polyhedral oligomeric silsesquioxane (meth)acrylate, which can comprise a fluorinated group, or mixtures thereof, in proportions by mass of Y ranging from 1% to 99% and preferably from 10% to 80%, with respect to the block comprising methyl methacrylate.

According to another variant of the invention, consideration may also be given to block copolymers, one of the blocks of which is a carbosilane, the other block comprising either styrene, or styrene and at least one comonomer X, or methyl methacrylate, or methyl methacrylate and at least one comonomer Y, X being chosen from the following entities: styrene, which is hydrogenated or partially hydrogenated, cyclohexadiene, cyclohexene, cyclohexane, styrene substituted by one or more fluoroalkyl groups, or mixtures thereof, in proportions by mass of X ranging from 1% to 99% and preferably from 10% to 80%, with respect to the block comprising styrene; Y being chosen from the following entities: fluoroalkyl (meth)acrylate, particularly trifluoroethyl methacrylate, dimethylaminoethyl (meth)acrylate, globular (meth)acrylates, such as isobornyl (meth)acrylate or halogenated isobornyl (meth)acrylate, halogenated alkyl (meth)acrylate, naphthyl (meth)acrylate, polyhedral oligomeric silsesquioxane (meth)acrylate, which can comprise a fluorinated group, or mixtures thereof, in proportions by mass of Y ranging from 1% to 99% and preferably from 10% to 80%, with respect to the block comprising methyl methacrylate.

Regarding the number-average molecular mass of the block copolymers used in the invention, measured by SEC with polystyrene standards, it may be between 2000 g/mol and 80 000 g/mol, preferably between 4000 g/mol and 20 000 g/mol, and even more particularly between 6000 g/mol and 15 000 g/mol, with a dispersity index of from 1.00 to 2 and preferably from 1.05 to 1.4.

The ratios between the constituent blocks will be chosen in the following way:

The various mesostructures of the block copolymers depend on the volume fractions of the blocks. Theoretical studies carried out by Masten et al. in “Equilibrium behavior of symmetric ABA triblock copolymers melts. The Journal of chemical physics, 1999” 111(15): 7139-7146, show that, by varying the volume fractions of the blocks, the mesostructures may be spherical, cylindrical, lamellar, gyroidal, etc. For example, a mesostructure showing packing of hexagonal-compact type may be obtained with volume fractions of ˜70% for one block and ˜30% for the other block.

Thus, to obtain lines, use will be made of a linear or non-linear block copolymer of AB, ABA or ABC type having a lamellar mesostructure. To obtain spots, use will be made of block copolymers of the same type, but which have spherical or cylindrical mesostructures, and with the matrix domain being degraded. To obtain holes, use will be made of block copolymers of the same type, which have spherical or cylindrical mesostructures, and with the cylinders or the spheres of the minority phase being degraded.

Furthermore, block copolymers having high values of x, the Flory-Huggins parameter, will have a strong phase separation of the blocks. This is because this parameter is relative to the interactions between the chains of each of the blocks. A high value of x signifies that the blocks move as far away as possible from one another, which will result in good resolution of the blocks, and therefore a low line roughness.

Systems of block copolymers with a high Flory-Huggins parameter (i.e. above 0.1 at 298 K) and more particularly polymeric blocks containing heteroatoms (atoms other than C and H), and even more particularly Si atoms, will thus be preferred.

### Phase Segregation:

The treatments suitable for promoting the self-assembly of block copolymers linked to the segregation behavior may be thermal annealing, typically above the glass transition temperatures (Tg) of the blocks, which can range from 10 to 250° C. above the highest Tg, exposure to solvent vapors, or else a combination of these two treatments or alternatively a microwave treatment. Preferably, it is a heat treatment, the temperature of which will depend on the blocks chosen and on the mesostructure order-disorder temperature. Where appropriate, for example when the blocks are judiciously chosen, a simple evaporation of the solvent will be sufficient, at ambient temperature, to promote the self-assembly of the block copolymer.

### The Substrates:

The process of the invention is applicable on the following substrates: silicon, silicon having a native or thermal oxide layer, hydrogenated or halogenated silicon, germanium, hydrogenated or halogenated germanium, platinum and platinum oxides, tungsten and tungsten oxides, gold, titanium nitrides, graphenes, and resins used by those skilled in the art in optical lithography. Preferably, the surface is inorganic and more preferably silicon. More preferably still, the surface is silicon having a native or thermal oxide layer.

The process for producing a self-assembled block copolymer film on a substrate according to the invention comprises:

a step of depositing a solution containing a blend of block copolymer and of random or gradient copolymers according to techniques known to those skilled in the art, for instance the “spin-coating”, “doctor blade”, “knife system” or “slot die system” technique, or combinations thereof,

then the solution containing the blend of block copolymer and of random or gradient copolymers is subjected to a heat treatment allowing the phase segregation inherent in the self-assembly of block copolymers and also the hierarchization of the block copolymer/random copolymer system, i.e. the migration of the random copolymer between the layer of block copolymer and the substrate.

The process of the invention aims to form a layer containing the blend of block copolymer and of random or gradient copolymers which is typically less than 300 nm and preferably less than 100 nm.

According to one preferred form of the invention, the block copolymers used for the blend deposited on the surfaces treated by means of the process of the invention are preferably linear or star diblock copolymers or triblock copolymers.

The surfaces treated by means of the process of the invention are advantageously used in applications in lithography, or the preparation of porous membranes or catalysis supports for which one of the domains formed during the self-assembly of the block copolymer is degraded in order to obtain a porous structure.

### EXAMPLES

### a) Preparation of a Random Copolymer by Radical Polymerization

### Example 1

### Preparation of a Hydroxy-Functionalized Alkoxyamine from the Commercial Alkoxyamine BlocBuilder®MA

The following are introduced into a 1 l round-bottomed flask purged with nitrogen:
226.17 g of BlocBuilder®MA (1 equivalent)
68.9 g of 2-hydroxyethyl acrylate (1 equivalent)
548 g of isopropanol.

The reaction mixture is refluxed (80° C.) for 4 h and then the isopropanol is evaporated off under vacuum. 297 g of hydroxy-functionalized alkoxyamine are obtained in the form of a very viscous yellow oil.

### Example 2

### Experimental Protocol for Preparing Polystyrene/Poly(Methyl Methacrylate) (PS/PMMA) Polymers from the Hydroxy-Functionalized Alkoxyamine Prepared According to Example 1

Toluene, and also the monomers such as styrene (S) and methyl methacrylate (MMA), and the hydroxy-functionalized alkoxyamine, are placed in a stainless steel reactor equipped with a mechanical stirrer and a jacket. The mass ratios between the various styrene (S) and methyl methacrylate (MMA) monomers are described in table 1 hereinafter. The toluene feedstock by mass is fixed at 30% relative to the reaction medium. The reaction mixture is stirred and degassed by bubbling nitrogen at ambient temperature for 30 minutes.

The temperature of the reaction medium is then brought toll 5° C. The time t=0 is triggered at ambient temperature. The temperature is maintained at 115° C. throughout the polymerization until a conversion of the monomers of about 70% is reached. Samples are taken at regular intervals in order to determine the polymerization kinetics by gravimetric analysis (measurement of dry extract).

When the 70% conversion is reached, the reaction medium is cooled to 60° C. and the solvent and residual monomers are evaporated off under vacuum. After evaporation, methyl ethyl ketone is added to the reaction medium in an amount such that a solution of polymer of about 25% by mass is produced.

This polymer solution is then introduced dropwise into a beaker containing a nonsolvent (heptane), so as to cause the polymer to precipitate. The mass ratio between the solvent and nonsolvent (methyl ethyl ketone/heptane) is about 1/10. The precipitated polymer is recovered in the form of a white powder after filtration and drying.

TABLE 1

| | Initial state of reaction | | | | | | | |
|---|---|---|---|---|---|---|---|---|
| | Initial mass | | Mass ratio | | | | | |
| | composition | | of initiator | | | | | |
| | of the | Nature of | relative to | | | | | |
| | S/MMA | the initiator | the S, MMA | Copolymer characteristics | | | | |
| Copolymers | monomers | used | monomers | % PS^{(a)} | Mp^{(a)} | Mn^{(a)} | Mw^{(a)} | PI^{(a)} |
| 1 | 58/42 | alkoxyamine | 0.03 | 64% | 16 440 | 11 870 | 16 670 | 1.4 |
| | | of example 1 | | | | | | |
| 2 | 58/42 | alkoxyamine | 0.02 | 60% | 49 020 | 23 150 | 46 280 | 2.0 |
| | | of example 1 | | | | | | |

^{(a)}Determined by size exclusion chromatography. The polymers are dissolved at 1 g/l in BHT-stabilized THF. The calibration is carried out using monodisperse polystyrene standards. Double detection by means of refractive index and UV at 254 nm makes it possible to determine the percentage of polystyrene in the polymer.

### b) Synthesis of the Block Copolymer

### Example 3

### Synthesis of the PLA-PDMS-PLA Triblock Copolymer

The products used for this synthesis are an initiator and homopolymer HO-PDMS-OH sold by Sigma-Aldrich, a racemic lactic acid, in order to avoid any problem associated with crystallization, an organic catalyst in order to avoid metal contamination problems, triazabicyclodecene (TBD) and toluene.

The volume fractions of the blocks were determined so as to obtain cylinders of PLA in a matrix of PDMS, i.e. approximately 70% of PDMS and 30% of PLA.

### Example 4

### Self-Assembly of a PLA-b-PDMS-b-PLA Triblock Copolymer

The block copolymer described in this study was chosen according to the needs of lithography, i.e. cylinders in a matrix, used as masks for creating cylindrical holes in a substrate after etching and degradation The desired morphology is therefore cylinders of PLA in a matrix of PDMS.

### 1st Step:

Preparation of a mixture of a solution containing either 5 or 10 mg of PS/PMMA random copolymer obtained according to example 2, and 15 mg of PLA/PDMS block copolymer obtained according to example 3, —the solution is made up to 1 g of solution with an appropriate solvent, PGMEA (propylene glycol monomethyl ether acetate). Next, 100 μl of this solution are deposited on a silicon substrate having a surface area of 1.4×1.4 cm² by spin-coating for 30 s.

### 2nd Step:

Annealing is carried out: heat treatment allowing the promotion of phase segregation. The substrate on which the solution according to step 1 has been deposited is placed on a hot plate at 180° C. for 1 h 30, at a temperature close to the order-disorder transition temperature of the block copolymer in order to neutralize the polymer film/substrate interfacial energies.

The example described demonstrates the formation of an orthogonal cylindrical hexagonal network of PLA in a matrix of PDMS from a blend of PLA-b-PDMS-b-PLA block copolymer, containing a volume fraction of PDMS equal to 72.7%, with the PS-r-PMMA random copolymer containing 57.8% of PS.

Reference may be made to FIG. 1 which shows four AFM images obtained according to the atomic force microscopy (AFM) imaging technique. The AFM images (a) and (b) correspond respectively to a film of PLA-b-PDMS-b-PLA deposited on a brush of PS-r-PMMA, and a blend of 75% by mass of PLA-b-PDMS-b-PLA and 25% by mass of PS-r-PMMA, without heat treatment.

The images (c) and (d) correspond to (a) and (b) respectively after heat treatment for 1 h 30 at 180° C.

Reference may also be made to FIG. 2a which represents Auger electron emission spectra for a film thermally annealed at 180° C. for 1 h 30, composed of PLA-b-PDMS-b-PLA deposited on a brush grafted, beforehand, with PS-r-PMMA, and, by way of comparison, to FIG. 2b which represents Auger electron emission spectra for a film composed of a mixture of 75/25% by mass of PLA-b-PDMS-b-PLA and PS-r-PMMA respectively.

DSC (acronym for differential scanning calorimetry) and SAXS (acronym for small-angle X-ray scattering) analyses confirm, on the one hand, that the mixtures are not miscible, and, on the other hand, that the mass structures are identical to that of the block copolymer alone, namely cylindrical hexagonal structures.

The atomic force microscopy images and, for example, image (d) of FIG. 1 show a hexagonal network of PLA cylinders oriented perpendicular to the surface in a PDMS matrix. Moreover, these results are similar to those observed during the grafting of the PS-rand-PMMA brush shown in the image (c) of FIG. 1.

Furthermore, Auger electron emission analyses, shown by FIGS. 2a and 2b, demonstrate that the behaviors of the films are identical between a film of block copolymer deposited on a brush of random copolymer, shown by FIG. 2a (image (a)), and a blend of 75/25% by mass of block copolymer and of random copolymer respectively shown by FIG. 2b (image (b)).

Consequently, during the thermal annealing, the chains of the PS-r-PMMA random copolymer migrate toward the substrate and act as a layer for neutralization of the surface with respect to the block copolymer.

Thus, a layer of random copolymer is formed between the film of PLA-b-PDMS-b-PLA block copolymer and the substrate, neutralizing the interfacial energies. Consequently, the PDMS and PLA domains no longer have preferential interactions with the substrate, and a structure of PLA cylinders oriented perpendicular to the surface in a PDMS matrix is obtained during the annealing step.

1. A process for producing a film of self-assembled block copolymer on a substrate, wherein the process comprises the following steps:
depositing, on a substrate, a solution containing a blend of a block copolymer and a random or gradient copolymer wherein the block copolymer and the random or gradiant copolymer are of different chemical nature and are immiscible,
annealing treatment allowing the promotion of the phase segregation inherent in the self-assembly of block copolymers.

2. The process as claimed in claim 1, wherein the solution contains a random copolymer, the block copolymer has the general formula A-b-B or A-b-B-b-A and the random copolymer has the general formula C-r-D; the monomers of the random copolymer being different than those present respectively in each of the blocks of the block copolymer.

3. The process as claimed in claim 1, wherein the random or gradient copolymer is prepared by radical polymerization.

4. The process as claimed in claim 1, wherein the random or gradient copolymer is prepared by controlled radical polymerization.

5. The process as claimed in claim 1, wherein the random or gradient copolymer is prepared by nitroxide-controlled radical polymerization.

6. The process as claimed in claim 5, wherein the nitroxide is N-(tert-butyl)-1-diethylphosphono-2,2-dimethylpropyl nitroxide.

7. The process as claimed in claim 1, wherein the block copolymer is selected from the group consisting of linear and star diblock copolymers and triblock copolymers.

8. The process as claimed in claim 1, wherein the block copolymer comprises at least one PLA block and at least one PDMS block.

9. The process as claimed in claim 5, wherein the random or gradient copolymer comprises methyl methacrylate and styrene.

10. The process as claimed in claim 1, wherein the annealing treatment is obtained by thermal or solvent-vapor treatment or microwave treatment.

11. A method for making a mask for lithography applications or a support for the localization of magnetic particles for information storage or guides for the formation of inorganic structures, wherein the method comprises using a film obtained by the process as claimed in claim 1.

12. A method of making a porous membrane or a catalyst support, comprising using a film obtained by the process as claimed in claim 1 and eliminating one of the domains of the block copolymer.
